(19) United States
(12) Patent Application Publication
(10) Pub. No.: US 2010/0148153 A1
(43) Pub. Date: Jun. 17, 2010

(54) Group III-V devices with delta-doped layer under channel region

(76) Inventors: Mantu K. Hudait, Portland, OR (US); Peter G. Tolchinsky, Beaverton, OR (US); Robert S. Chau, Beaverton, OR (US); Marko Radosavljevic, Beaverton, OR (US); Ravi Pillarisetty, Portland, OR (US); Aaron A. Budrevich, Portland, OR (US)

Correspondence Address: INTEL CORPORATION;c/o CPA Global, P.O. BOX 52050, MINNEAPOLIS, MN, 55402, US

(21) Appl. No.: 12/316,878

(22) Filed: Dec. 16, 2008

(51) Int. Cl. H01L 29/78

(52) U.S. Cl. 257/24; 257/E29.255; 257/E29.069

(57) ABSTRACT

A group III-V material device has a delta-doped region below a channel region. This may improve the performance of the device by reducing the distance between the gate and the channel region.

### BACKGROUND

### Background of the Invention

Most integrated circuits today are based on silicon, a Group IV element of the Periodic Table. Compounds of Group III-V elements such as gallium arsenide (GaAs), indium antimonide (InSb), indium phosphide (InP), and indium gallium arsenide (InGaAs) are known to have far superior semiconductor properties than silicon, including higher electron mobility and saturation velocity. These materials may thus provide superior device performance.

### BRIEF DESCRIPTION OF THE DRAWINGS

FIG. 1 is a cross sectional side view that illustrates a group III-V material quantum well transistor device.

FIG. 2 is a cross sectional side view that illustrates the substrate.

FIG. 3 is a cross sectional side view that illustrates a buffer region that is formed on the substrate.

FIG. 4 is a cross sectional side view that illustrates the bottom barrier region on the buffer region.

FIG. 5 is a cross sectional side view that illustrates a delta-doped region on the bottom barrier region.

FIG. 6 is a cross sectional side view that illustrates the spacer region on the delta-doped region.

FIG. 7 is a cross sectional side view that illustrates the channel region.

FIG. 8 is a cross sectional side view that illustrates an upper barrier region on the quantum well channel region.

FIG. 9 is a cross sectional side view that illustrates a dielectric barrier region on the upper barrier region.

FIG. 10 is a cross sectional side view that illustrates a gate dielectric on the dielectric barrier region.

FIG. 11 is a cross sectional side view that illustrates a gate on the gate dielectric.

FIG. 12 is a cross sectional side view that illustrates the device in operation.

### DETAILED DESCRIPTION

In various embodiments, an apparatus and method relating to the formation of a group III-V material semiconductor device are described. In the following description, various embodiments will be described. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order, in series or in parallel, than the described embodiment. Various additional operations may be performed and/or described operations may be omitted in additional embodiments.

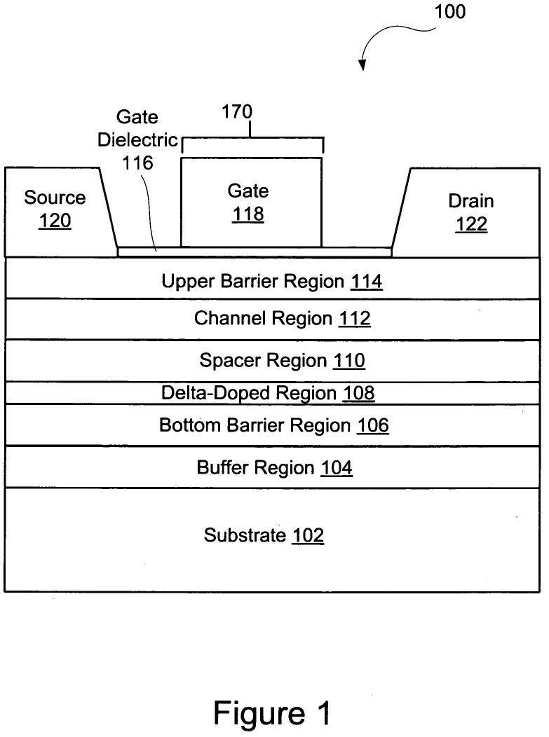

FIG. 1 is a cross sectional side view that illustrates a group III-V material quantum well transistor device 100 with a delta-doped region 108 below a channel region 112, according to one embodiment of the present invention. The delta-doped region 108 being positioned beneath the channel region 112 allows the distance between the channel region 112 and the gate electrode 118 to be smaller than if the delta-doped region 108 were above the channel region 112. This smaller distance in turn allows the gate length 170 of the device 100 to be lower than if the distance between the channel region 112 and the gate electrode 118 were greater. For example, in some embodiments, the device 100 can have a gate length 170 of lower than 20 nanometers. Devices 100 with smaller gate lengths 170 can potentially provide better performance with higher I_{ON}/I_{OFF}, higher cutoff frequency, reduced gate leakage, higher drive current, and/or reduced short channel effects in various embodiments. Further, devices 100 with smaller gate lengths 170 allow more transistors 100 to be formed on a given area of substrate 102, which means that products can be made at lower cost.

In the illustrated embodiment, the device 100 includes a substrate 102, which may be any material or materials on which the device 100 may be made. In some embodiments the substrate 102 may be a substantially single-crystal silicon material, a substantially single-crystal silicon material that is doped, a multi-crystal or multi-layer substrate 102. The substrate 102 may not comprise silicon in some embodiments, but may instead comprise a different substrate material, such as a GaAs or InP. The substrate 102 may include one or more material(s), device(s), or layer(s), or may be a single material without multiple layers.

There is a buffer region 104 on the substrate 102 in the illustrated embodiment. The buffer region 104 may function to accommodate for a lattice mismatch between the substrate 102 and regions above the buffer region 104 and to confine lattice dislocations and defects.

There is a lower barrier region 106 on the buffer region 104, a delta-doped region 108 on the lower barrier region 106, a spacer region 110 on the delta-doped region 108, a channel region 112 on the spacer region 110, and an upper barrier region 114 on the channel region 112 in the illustrated embodiment. The delta-doped region 108 is doped according to the design of the device 100 and the targeted threshold voltage of the device 100. Note that the term “delta-doped region” as used herein also encompasses a modulation doped region, and some embodiments of the device 100 may have a modulation doped region 108 instead of a delta-doped region 108; the term “delta-doped region” as used herein encompasses both embodiments. The delta-doped region 108 is below the channel region 112, which allows the distance between the channel region 112 and the gate 118 to be less than if the delta-doped region 108 were above the channel region 112. The channel region 112 and delta-doped region 108 are sandwiched between the upper and lower barrier regions 114, 106.

There is a gate dielectric 116 on the upper barrier region 118. On the high-k gate dielectric layer 116 is a gate electrode 118, the material of which may be chosen based on a desired work function. The device 100 also has source and drain regions 120 and 122. As illustrated, the device 100 is a recessed gate 118 device 100, although in other embodiments it may be a different type of device 100 that lacks a recessed gate 118.

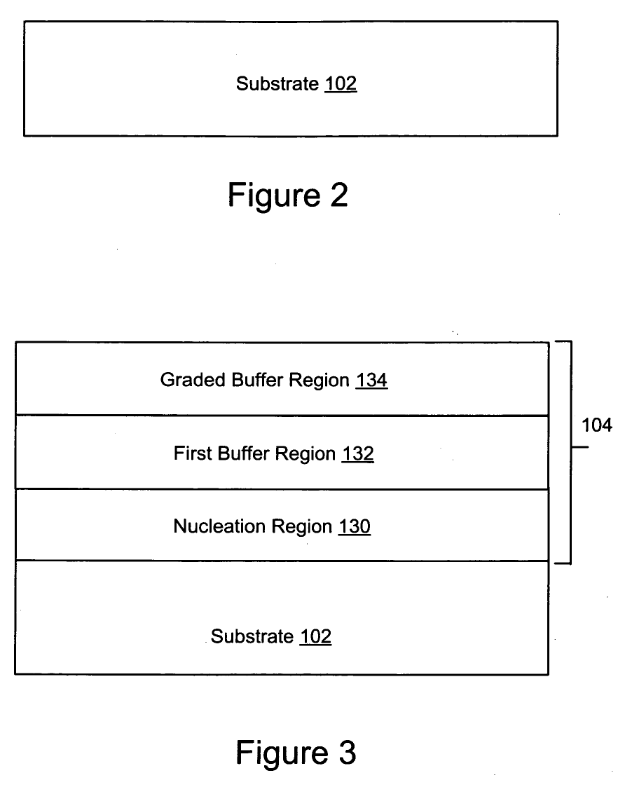

FIGS. 2 through 12 are cross sectional side views that illustrate how the device 100 may be made, and provide additional details about embodiments of the invention.

FIG. 2 is a cross sectional side view that illustrates the substrate 102, according to one embodiment of the invention. The substrate 102 may comprise high-resistivity p-type or n-type vicinal silicon material having regular arrays of double-stepped (100) terraces across the substrate surface in some embodiments. A vicinal surface may be prepared by offcutting the substrate 102 from an ingot. In some embodiments, the (100) substrate surface is offcut at an angle between 2 and 8 degrees towards the [110] direction. In a particular embodiment, the (100) substrate surface is offcut at an angle of about 4 degrees towards the [110] direction. A vicinal surface is a higher order crystal plane of the silicon substrate 102, such as, but not limited to the (211), (511), (013), (711) planes.

The substrate 102 surface on which the device 100 is to be formed may have a resistance between about 1 ohm and about 50,000 ohms per centimeter. The high resistivity may be achieved by a low dopant concentration, lower than about 10¹⁶ carriers/cm³.

In some embodiments the substrate 102 may be a substantially single-crystal silicon material, a substantially single-crystal silicon material that is doped, a multi-crystal or multi-layer substrate 102. In various embodiments, the substrate 102 could comprise germanium, germanium on silicon, or could be a silicon-on-insulator substrate 102. The substrate 102 may not comprise silicon in some embodiments, but may instead comprise a different material, such as a different semiconductor or a group III-V material such as GaAs or InP. The substrate 102 may include one or more material(s), device(s), or layer(s), or may be a single material without multiple layers.

FIG. 3 is a cross sectional side view that illustrates a buffer region 104 that is formed on the substrate 102 in one embodiment. The buffer region 104 may function to accommodate for a lattice mismatch between the substrate 102 and regions above the buffer region 104 and to confine lattice dislocations and defects. In the illustrated embodiment, the buffer region 104 has multiple regions: a nucleation region 130, a first buffer region 132, and a graded buffer region 134, although in other embodiments the buffer region 104 may have different numbers of regions or simply be a single region.

The nucleation region 130 comprises gallium arsenide in one embodiment, although other materials such as GaSb or AlSb may be used in other embodiments. (Note that as used herein, when materials designated by their elements without subscripts, these designations encompass any mix of percentages of the elements. For example, “InGaAs” encompasses InₓGa₁₋ₓAs, with x ranging between zero (GaAs) and one (InAs). Similarly, InAlAs encompasses In_{0.52}Al_{0.48}As.) It is formed by molecular beam epitaxy (MBE), migration enhanced epitaxy (MEE), metal-organic chemical vapor deposition (MOCVD), atomic layer epitaxy (ALE), chemical beam epitaxy (CBE), or another suitable method. It has a thickness of less than about 500 angstroms in some embodiments. In embodiments where the substrate 102 is a vicinal silicon material, the nucleation region 130 may be made sufficiently thick to fill all the terraces of the silicon substrate 102. In an alternative embodiment, other suitable nucleation region 130 materials or thicknesses may be used, or the nucleation region 130 may be ommitted.

On the nucleation region 130 is a first buffer region 132 in the illustrated embodiment. In an embodiment, the first buffer region 132 comprises a GaAs material, although other materials, such as InAlAs, AlSb, or other materials may be used. In an embodiment, the first buffer region 132 consists substantially the same material as the nucleation region 130. The buffer region 132 may also be formed by molecular beam epitaxy (MBE), migration enhanced epitaxy (MEE), metal-organic chemical vapor deposition (MOCVD), atomic layer epitaxy (ALE), chemical beam epitaxy (CBE), or another suitable method. The first buffer region 132 may have a thickness of less than one micron, between 0.3 microns and one micron, or another thickness in various embodiments.

The first buffer region 132 may be formed by the same process used to form the nucleation region 130 in some embodiments. In such an embodiment, the growth of the first buffer layer 108 may be performed at a higher temperature than that used for the nucleation layer 104. While first buffer region 132 may considered and is shown as a separate region than nucleation region 130, both regions 130, 132 may be considered buffers, with region 132 thickening the III-V buffer region started by nucleation region 130, and gliding dislocations. The film quality of region 132 may be superior to that of the nucleation region 132 because it may be formed at a higher growth temperature. Also, during the formation of region 132, the flux rate can be relatively high because the polar nucleation region 130 may eliminate danger of anti-phase domains (APD) formation.

In the illustrated embodiment, there is a graded buffer region 134 on the first buffer region 132. In the illustrated embodiment, the graded buffer region 134 comprises indium aluminum arsenide InₓAl₁₋ₓAs, with x ranging between zero (or another selected starting amount) and the amount of In desired in the bottom barrier region, although the graded buffer region 134 may comprise other materials and may be doped. For example, the graded buffer region 134 may comprise AlAs adjacent the first buffer region 132 (thus, x=0), with increasing amounts of In present (although not necessarily at a linear increase rate) higher in the graded buffer region 134 so that the graded buffer region 134 comprises In_{0.52}Al_{0.48}As adjacent the bottom barrier region 106. In some embodiments, the top of the graded buffer region 134 comprises InₓAl₁₋ₓAs, with x being between 0.52 and 0.70. The graded buffer region 134 has a thickness of less than about 5 microns in an embodiment. In other embodiments, it may have sufficient thickness that most defects present at its bottom surface are not present at its top surface. Any suitable method may be used to form the graded buffer region 134.

Note that some embodiments may lack a buffer region 132 and/or graded buffer region 134. For example, in embodiments where the substrate 102 comprises a group III-V material, the device 100 may lack buffer region 132 and/or graded buffer region 134.

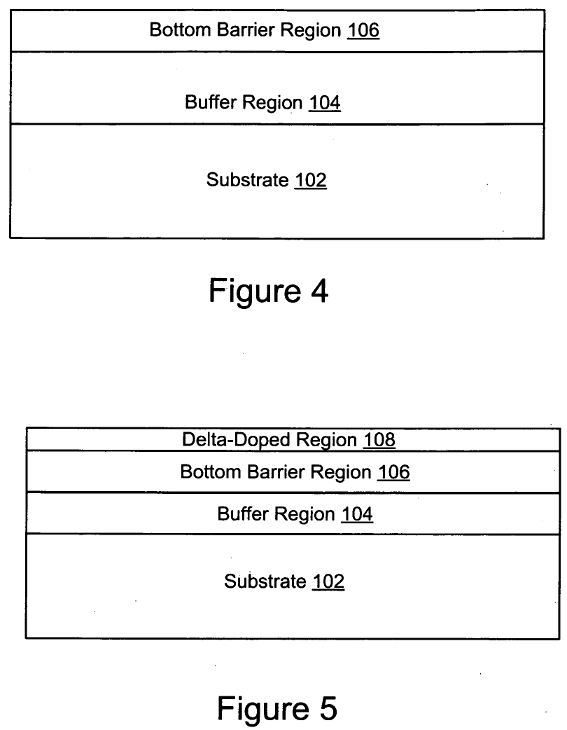

FIG. 4 is a cross sectional side view that illustrates the bottom barrier region 106 on the buffer region 104, according to one embodiment. The bottom barrier region 106 comprises InAlAs in the illustrated embodiment, although in other embodiments it may comprise other materials such as InAlSb or InP. In embodiments where the bottom barrier region 106 comprises InAlAs, it may comprise InₓAl₁₋ₓAs, with x between 0.52 and 0.70, although different compositions may be used in other embodiments. The bottom barrier region 106 may be doped. The bottom barrier region 106 may comprise a material with a higher band gap than the material of which the channel region 112 is comprised. Any suitable method, such as those listed as possible to form the buffer region 104, above, may be used to form the bottom barrier region 106. In some embodiments, the bottom barrier region 106 may have a thickness between about one micron and three microns, although it may have different thicknesses in other embodiments.

FIG. 5 is a cross sectional side view that illustrates a delta-doped region 108 on the bottom barrier region 106, according to one embodiment. The delta-doped region 108 may comprise the same material as the bottom barrier region 106, with the addition of a dopant or dopants. The dopant used in the delta-doped region 108 may be Te, Si, Be, or another dopant. There may be a dopant density in the delta-doped region 108 of between about 1×10¹¹/cm² to about 8×10¹²/cm² in some embodiments, although different dopant densities may be used. The density of dopants may be chosen based by the device 100 design and targeted threshold voltage of the device. In another embodiment, the delta-doped region 108 may comprised Si that is doped. In an embodiment, the delta-doped region 108, the bottom barrier region 106 and/or other regions may be formed with a continuous growth process. For example, the bottom barrier region 106 can comprise InAlAs formed in a chamber into which In, Al, and As are flowing and to form the delta-doped region 108 the flows of In and Al are stopped while a flow of Si is begun. In other embodiments, different ways to form the regions may be used. In some embodiments, the delta-doped region 108 may have a thickness of less than about 5 angstroms, although it may have different thicknesses in other embodiments.

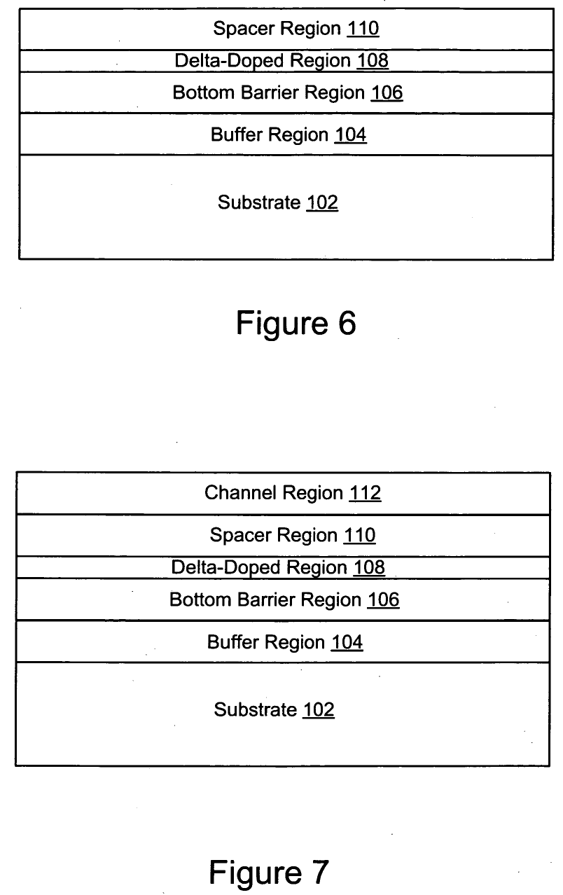

FIG. 6 is a cross sectional side view that illustrates the spacer region 110 on the delta-doped region 108, according to one embodiment. The spacer region 110 may comprise the same material as the bottom barrier region 106 in an embodiment. For example, in an embodiment where the bottom barrier region 106 comprises In_{0.52}Al_{0.48}As, the spacer region 110 may also comprise In_{0.52}Al_{0.48}As. In an embodiment, the spacer region 110 may consist substantially of the same material as the bottom barrier region 106. In other embodiments, the spacer region 110 may comprise other materials. The spacer region 110 may be formed by any suitable method, and may be formed by the same method used to form the bottom barrier region 106.

FIG. 7 is a cross sectional side view that illustrates the channel region 112 according to one embodiment of the invention. The channel region 112 may be a quantum well channel region. This quantum well channel region 112 comprises a group III-V material. A group III-V material is a material that has both a group III material and a group V material. For example, the group III-V material of the channel region 112 is InGaAs in the illustrated embodiment, although in other embodiments it may comprise other materials such as InSb or InAs. In an embodiment where the quantum well channel region 112 comprises InGaAs, the ratio of In to Ga may be selected to give the quantum well channel region 112 a rough lattice match to surrounding regions. For example, in an embodiment where the spacer region 110 comprises In_{0.52}Al_{0.48}As, the channel region 112 may comprise In_{0.53}Ga_{0.47}As. In other embodiments, the channel region 112 may comprise InₓGa₁₋ₓAs, with x being between about 0.53 and about 1.0 (in which case there is substantially no Ga). The different ratio of In to Ga may be selected to provide a strain to the channel region 112. Any suitable method, such as those listed as possible to form the buffer region 104, above, may be used to form the quantum well channel region 112. In some embodiments, the quantum well channel region 112 may have a thickness between about 3 nanometers and twenty nanometers, although it may be less or more than that: it may have different thicknesses in other embodiments.

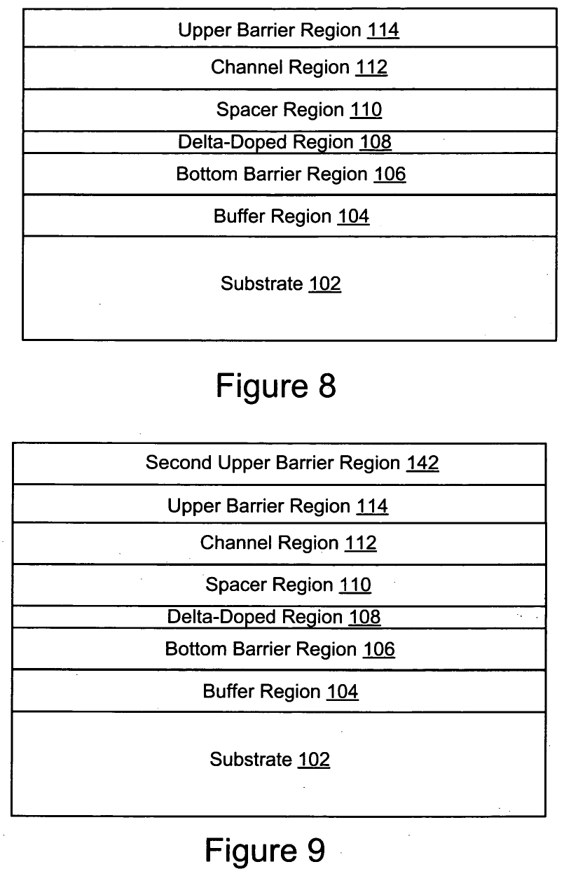

FIG. 8 is a cross sectional side view that illustrates an upper barrier region 114 on the quantum well channel region 112, according to one embodiment. The upper barrier region 114 comprises InAlAs in the illustrated embodiment, although in other embodiments it may comprise other materials. In an embodiment where the upper barrier region 114 comprises InAlAs, there may be a ratio of In to Al of about 52 to 48 (In_{0.52}Al_{0.48}As). The upper barrier region 114 may comprise a material with a higher band gap than the material of which the quantum well channel region 112 is comprised. In an embodiment, the upper barrier region 114 comprises the same material as the bottom barrier region 106 (e.g., if the bottom barrier region 106 comprises In_{0.60}Al_{0.40}As, the upper barrier region 114 also comprises In_{0.60}Al_{0.40}As). In an embodiment, the upper barrier region 114 consists of substantially the same material as the bottom barrier region 106. In other embodiments, the upper and bottom barrier regions 106, 114 may comprise different materials. Any suitable method, such as those listed as possible to form the buffer region 104, above, may be used to form the upper barrier region 114. In some embodiments, the upper barrier region 114 may be very thin, such as less than fifty nanometers. In an embodiment, the upper barrier region 114 may have a thickness of as small as about 3 nanometers, although it may have different thicknesses that are greater or less. This thickness may be chosen based on the targeted threshold voltage for the device 100.

FIG. 9 is a cross sectional side view that illustrates a dielectric barrier region 142 on the upper barrier region 114, according to one embodiment. The dielectric barrier region 142 illustrated in FIG. 9 is a second upper barrier region that comprises an InP material, although other materials may be used in other embodiments. In an embodiment, the dielectric barrier region 142 has a thickness less than about 2 nanometers. In an embodiment, the dielectric barrier region 142 has a thickness of one nanometer or less. In other embodiments, the dielectric barrier region 142 may have different thicknesses. In an embodiment, the dielectric barrier region 142 may be formed to a first thickness, then etched or otherwise thinned to its final thickness.

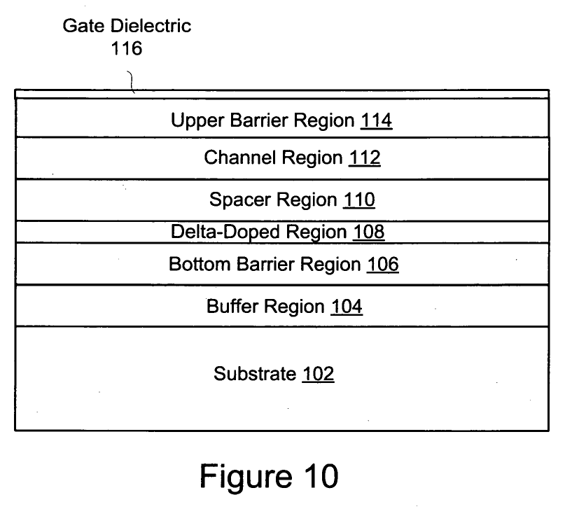

FIG. 10 is a cross sectional side view that illustrates a gate dielectric 116 on the dielectric barrier region 142, according to one embodiment. The gate dielectric 116 may comprise a high-k dielectric material such as Al₂O₃, although other materials such as La₂O₃, HfO₂, ZrO₂, TaO₅, or ternary complexes such as LaAlₓO_{y}, HfₓZr_{y}O_{z} or other materials may be used in other embodiments. In embodiments where the gate dielectric 116 is Al₂O₃, the Al₂O₃ may be deposited using trimethylaluminum (TMA) and water precursors with and ALD process in one embodiment, although other methods to form it may be used. In some embodiments, the gate dielectric 116 may have a thickness between about 0.7 nanometers and 5 nanometers, although it may have different thicknesses in other embodiments.

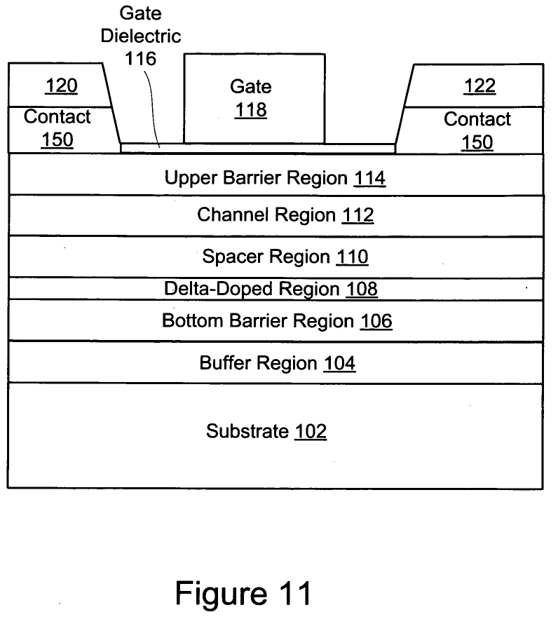

FIG. 11 is a cross sectional side view that illustrates a gate 118 on the gate dielectric 116, and source and drain regions 120, 122 on either side of the gate 118, according to one embodiment. In the illustrated embodiment, the gate 118 is a recessed gate of a transistor, so portions of a source/drain layer are removed to recess the gate 118, leaving the source and drain regions 120, 122. The recessed source, drain, and gate may be formed by e-beam evaporation of metal and lift-off or float-off in an embodiment. In other embodiments, other types of transistors or other devices 100 may be formed, which may lack the recesses in the source/drain layer.

The gate electrode 118 may comprise a metal-containing material such as Pt/Au, Ti/Au, Ti/Pt/Au, or another material or materials. In some embodiments, the gate has a work function of over 4.5 eV, although other workfunction may be possible.

In the illustrated embodiment, the source and drain regions 120, 122 are on contact regions 150. These separate contact regions 150 may be absent in some other embodiments. In an embodiment, the contact regions 150 may comprise InGaAs (InₓGa₁₋ₓAs), and may be graded or have a substantially constant ratio of In to Ga through their thicknesses. In an embodiment, the top region of the contact regions 150 may comprise In_{0.53}Ga_{0.47}As, but other compositions may be used in other embodiments.

In one embodiment, the source and drain regions 120, 122 may comprise NiGeAu. In another embodiment, the source and drain regions 120, 122 may comprise TiPtAu. In other embodiments, the source and drain regions 120, 122 may comprise another material.

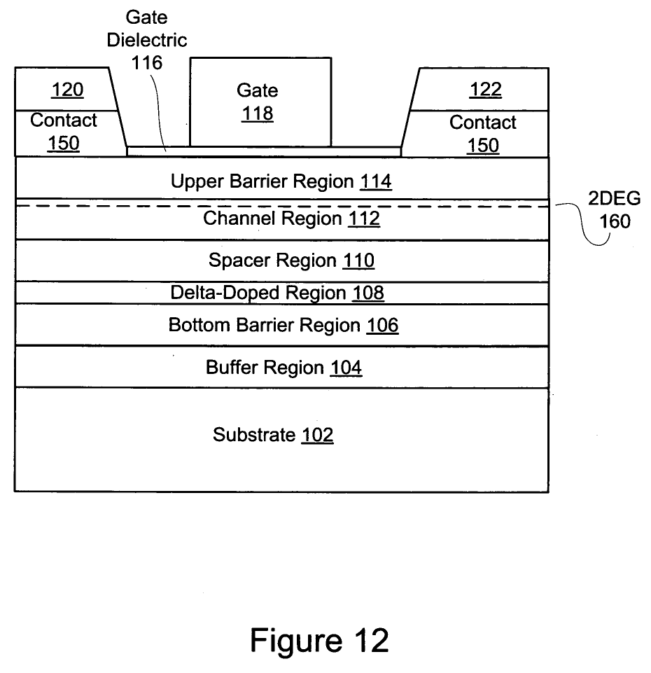

FIG. 12 is a cross sectional side view that illustrates the device 100 in operation. In the illustrated embodiment, there is a two dimensional electron gas (2DEG) in the upper portion of the channel region 112 while the device 100 is in operation. As the delta-doped region 108 is below the channel region 112, the 2DEG is in the upper portion of the channel region 112 and the device 100 has less separation between the gate 118 and the 2DEG than if the delta-doped region 108 were above the channel region 112. This can provide numerous advantages to the device 100 such as reduced gate length, controlled short channel effects, enhancement mode operation, increased on-current, and/or higher I_{ON}/I_{OFF}.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on arid in immediate contact with the second layer unless such is specifically stated; there may be a third layer or other structure between the first layer and the second layer on the first layer. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

1. (canceled)

2. The device of claim 6, further comprising a gate dielectric between the gate electrode and the first upper barrier region, a source region on a first side of the gate electrode, and a drain region on a second side of the gate electrode opposite the first side.

3. The device of claim 6, wherein the gate electrode comprises a metal.

4. The device of claim 6, further comprising a substrate comprising Si under the lower barrier region.

5. The device of claim 4, further comprising a buffer region between the substrate and the lower barrier region.

6. A device comprising:
a lower barrier region comprising InAlAs;
a delta doped region on top of the lower barrier region;
a quantum well channel region comprising InGaAs on top of the delta doped region;
a first upper barrier region comprising InAlAs on top of the the quantum well channel region;
a gate electrode on top of the upper barrier region; and
a second upper barrier region comprising InP between the first upper barrier region and the gate electrode.

7. The device of claim 6, further comprising a gate dielectric region comprising a high-k material between the second upper barrier region and the gate electrode.

8. The device of claim 7, wherein the gate dielectric region comprises HfO₂, Al₂O₃, or TaO₅.

9. The device of claim 6, wherein the device is a transistor having a gate length less than or equal to 20 nanometers.

10. (canceled)

11. (canceled)

12. The transistor of claim 17, wherein both the upper barrier region and the lower barrier region comprise an In_{y}Al_{1-y}As material, where y is between 0.52 and 0.70.

13. The transistor of claim 17, wherein the delta-doped region comprises substantially the same material as the lower barrier region plus a dopant.

14. The transistor of claim 17, wherein the quantum well channel region comprises an InₓGa₁₋ₓAs material, where x is between 0.53 and 1.0.

15. (canceled)

16. (canceled)

17. A semiconductor transistor comprising:
a substrate;
a quantum well channel region comprising a group III-V material on the substrate;
a delta-doped region between the quantum well channel region and the substrate;
a first upper barrier region above the quantum well channel region;
a lower barrier region below the quantum well channel region;
a spacer region between the delta-doped region and the quantum well channel region;
a high-k gate dielectric region above first upper barrier region;
a gate electrode comprising a metal above the high-k gate dielectric region;
a source contact on a first side of the high-k gate dielectric region;
a drain contact on a second side of the high-k gate dielectric region opposite to the first side; and
a second upper barrier region between the first upper barrier region and the high-k gate dielectric region, the second upper barrier region comprising InP.

18. The transistor of claim 17, wherein the transistor is operable to generate a two dimensional electron gas in an upper portion of the quantum well channel region.

19. The transistor of claim 17, wherein the transistor does not include a delta-doped region above the quantum well channel region.

20. A transistor comprising:
a substrate comprising silicon;
a buffer layer on the substrate, the buffer layer comprising a graded In_{y}Al_{1-y}As material, with the y increasing as the distance from the substrate increases;
a lower barrier layer on the buffer layer, the lower barrier layer comprising an In_{y}Al_{1-y}As material, where y is between 0.52 and 0.70;
a delta-doped layer on the lower barrier layer, the delta-doped layer comprising an In_{y}Al_{1-y}As material that is substantially the same as the In_{y}Al_{1-y}As material of the lower barrier layer, plus a dopant;
a quantum well channel layer on the delta-doped layer, the quantum well channel layer comprising an InₓGa₁₋ₓAs material, where x is between 0.53 and 1.0;
a first upper barrier layer on the quantum well channel layer, the first upper barrier layer consisting of substantially the same material as the lower barrier layer;
a second upper barrier layer on the first upper barrier layer, the second upper barrier layer comprising InP;
a high-k gate dielectric layer on the second upper barrier layer;
a gate electrode on the high-k gate dielectric layer, the gate electrode comprising a metal;
a source contact on a first side of the gate electrode, the source contact comprising InGaAs; and
a drain contact on a second side of the gate electrode opposite the first side, the drain contact comprising InGaAs.

21. The device of claim 6, wherein the gate electrode comprises gold and further comprises a material selected from the group consisting of platinum and titanium.

22. The device of claim 6, further comprising a source region and a drain region, the source and drain regions comprising gold and further comprises at least one material selected from the group consisting of nickel, germanium, platinum and titanium.

23. The transistor of claim 17, wherein the gate electrode comprises gold and further comprises a material selected from the group consisting of platinum and titanium.

24. The transistor of claim 20, wherein the gate electrode comprises gold and further comprises a material selected from the group consisting of platinum and titanium.
